(19) United States
(12) Patent Application Publication
(10) Pub. No.: US 2025/0296222 A1
(43) Pub. Date: Sep. 25, 2025

(54) CABIN FOR MOBILE ROBOT, BODY ASSEMBLY AND MOBILE ROBOT

(71) Applicant: Beijing Youzhuju Network Technology Co., Ltd., Beijing (CN)

(72) Inventors: Guangzeng Chen, Beijing (CN); Tao Kong, Beijing (CN); Jiafeng Xu, Beijing (CN)

(21) Appl. No.: 19/033,404

(22) Filed: Jan. 21, 2025

(30) Foreign Application Priority Data
Mar. 22, 2024 (CN) 202410339478.0

(51) Int. Cl. B25J 9/00; B25J 19/00

(52) U.S. Cl. CPC B25J 9/0021; B25J 19/005; B25J 19/0054

(57) ABSTRACT

Embodiments of the disclosure provide a cabin for a mobile robot, a body assembly, and a mobile robot. The cabin includes a first housing; a second housing is coupled to a first open end of the first housing through a second open end, and the accommodating chamber that accommodates at least a plurality of motors; and a first side plate and a second side plate respectively arranged at two ends of the first housing and the second housing in an axial direction of the first housing, and the first side plate includes a first shaft hole, and a pair of first air inlets arranged respectively on two sides of the first shaft hole in a radial direction, the second side plate includes a second air inlet and a pair of second shaft holes; and output shafts of the plurality of motors.

### CROSS REFERENCE TO RELATED APPLICATION(S)

This application claims priority to Chinese Application No. 202410339478.0 filed on Mar. 22, 2024, entitled ‘CABIN FOR MOBLE ROBOT, BODY ASSEMBLY AND MOBILE ROBOT’, the disclosure of which is incorporated herein by reference in its entirety.

### FIELD

Example embodiments of the present disclosure generally relate to the field of robots, and in particular, to a cabin for a mobile robot, a body assembly, and a mobile robot.

### BACKGROUND

A robot's body may be considered a robot's hub. That is, the body is essentially a multifunctional integrated system comprising a cabin and various components therein. Normal operation of each component of the robot is protected and supported by the cabin.

The cabin of a traditional robot body is an overall complex structure formed by tightly connecting multiple components. However, due to its structural complexity, this leads to difficulties in the overall assembly of the body, low body strength, and high weight. Meanwhile, it also increases costs during the manufacturing process of individual components. In addition, due to poor heat dissipation performance of the traditional cabin, the high temperatures generated by various internal components (such as the electronic devices and the motors) cannot be timely discharged, thus resulting in performance degradation or damage of the components.

### SUMMARY

A purpose of the present disclosure is to provide a cabin for a mobile robot, a body assembly, and a mobile robot to at least partially solve the above problems and/or other potential problems existing in a conventional cabin.

In a first aspect of the present disclosure, a cabin for a mobile robot is provided. The cabin includes: a first housing including a first open end; a second housing including a second open end and adapted to be coupled on the first open end of the first housing via the second open end to form an accommodating chamber that accommodates chamber at least a plurality of motors; and a first side plate and a second side plate respectively arranged at two ends of the first housing and the second housing in an axial direction of the first housing to fix the first housing and the second housing, and the first side plate including a first shaft hole arranged coaxially with an axis of the first housing and a pair of first air inlets respectively arranged on two sides of the first shaft hole in a radial direction, the second side plate including a second air inlet arranged coaxially with the axis, and a pair of second shaft holes respectively arranged on two sides of the second air inlet in the radial direction, wherein output shafts of the plurality of motors are adapted to extend from the first shaft hole and the pair of second shaft holes respectively.

According to the cabin, various effects of simple structure, a high cabin strength, a small weight, a high assembly efficiency and the like can be achieved, a space utilization rate is effectively improved, and meanwhile, a good heat dissipation effect is maintained. In addition, other benefits will be described below in conjunction with corresponding embodiments.

In some embodiments, the accommodating chamber is adapted to receive a functional compartment for accommodating a controller, a pair of energy compartments for accommodating batteries, respectively, and a plurality of power compartments for accommodating the plurality of motors, respectively.

In some embodiments, the functional compartment is arranged to be aligned with the second air inlet in the axial direction and is communicated with outside via a functional opening of the second housing, the pair of energy compartments are respectively arranged on two sides of the functional compartment in the radial direction and are aligned with the pair of first air inlets, and the plurality of power compartments are respectively arranged to be aligned with the first shaft hole and the pair of second shaft holes, so that output shafts of the motors extend from corresponding shaft holes.

In some embodiments, the first housing and the second housing have a plurality of air outlets at positions proximate to the plurality of power compartments.

In some embodiments, the pair of energy compartments are detachably disposed in the accommodating chamber.

In some embodiments, the first housing and the second housing include a reinforcing isolation structure arranged between the functional compartment and the energy compartment.

In some embodiments, an exterior of the second housing away from a side of the first housing is configured as a platform and includes a plurality of coupling portions for coupling an external device to the cabin.

In some embodiments, the first opening end, the second opening end, a first side wall of the first side plate coupled with the first housing, and the second housing and the second side wall of the second side plate coupled with the first housing and the second housing are subjected to thickening treatment.

In some embodiments, the cabin further includes a functional opening arranged on an outer wall of the second housing away from the first housing to expose an interface unit for a controller to connect an external component.

In a second aspect of the present disclosure, a body assembly is provided. The body assembly includes the cabin of the first aspect described above; a controller coupled in the functional compartment of the cabin and including an interface unit adapted to be coupled to an external component via a functional opening of a second housing; a plurality of motors respectively coupled to the power bin of the cabin and adapted to be electrically connected to the controller; and a pair of batteries detachably arranged in the energy compartment of the cabin and adapted to provide power to the motors via the controller.

In some embodiments, the body assembly further includes: a plurality of heat dissipation fans respectively coupled to a pair of first air inlets and a second air inlets of the cabin, and adapted for cooling of the controller, the motors and the batteries.

In a third aspect of the present disclosure, a mobile robot is provided. The mobile robot includes the body assembly according to the second aspect.

It should be understood that the content described in the summary is not intended to limit key features or important features of the embodiments of the present disclosure, nor is it intended to limit a scope of the present disclosure. Other features of the present disclosure will become readily understood from the following description.

### BRIEF DESCRIPTION OF DRAWINGS

The above and other features, advantages, and aspects of various embodiments of the present disclosure will become more apparent from the following detailed description taken in conjunction with drawings. In the drawings, the same or similar reference numbers refer to the same or similar elements, wherein:

FIG. 1 illustrates an exploded view of a cabin according to some embodiments of the present disclosure; and

FIG. 2 and FIG. 3 illustrate schematic structural diagrams of a cabin according to some embodiments of the present disclosure.

### DETAILED DESCRIPTION

Embodiments of the present disclosure will be described in more detail below with reference to the drawings. While certain embodiments of the present disclosure are shown in the drawings, it should be understood that the present disclosure may be implemented in various forms, and should not be construed as limited to embodiments set forth herein, but rather, these embodiments are provided for a more thorough and complete understanding of the present disclosure. It should be understood that the drawings and embodiments of the present disclosure are for exemplary purposes only and are not intended to limit a scope of the present disclosure.

In a description of embodiments of the present disclosure, the terms “including” and the like should be understood to include “including but not limited to”. The term “based on” should be understood as “based at least in part on”. The terms “an embodiment” or “the embodiment” should be understood as “at least one embodiment”. The term “some embodiments” should be understood as “at least some embodiments”. Other explicit and implicit definitions may also be included below. The terms “first,” “second,” and the like may refer to different or identical objects. Other explicit and implicit definitions may also be included below.

As mentioned briefly above, the cabin of the traditional robot is complex in structure and poor in heat dissipation effect. The cabin of the traditional robot is an overall complex structure formed by tightly connecting multiple components. Thus, each component needs to be precisely shaped and positioned to ensure optimal performance. However, this complex process undoubtedly increases manufacturing and assembly time, and also increases costs.

Meanwhile, if the structure of the cabin is complex, difficulty of assembling is greater. Since precise assembly needs to be performed between components, if one of the components has an assembly error, it may affect a working performance of the entire cabin, and may even cause some functions to be completely unavailable. In addition, connection between the various components may become a weak point and may be easily damaged during use.

In addition, in dense operation of various electronic devices and motors inside the cabin, the cabin of the robot may generate a large amount of heat. The traditional cabin does not have an effective heat dissipation system, so that the heat may cause thermal stress to internal electronic devices, may affect an operation efficiency of the robot, and may even cause overheating and damage of the electronic devices.

In order to address or at least partially address the above issues or other potential problems of the cabin of traditional schemes, embodiments of the present disclosure provide a scheme of a cabin for a mobile robot, a body assembly, and a mobile robot. According to the scheme of embodiments of the present disclosure, the cabin includes a first housing, a second housing, a first side plate and a second side plate. Further, the first housing includes a first open end, and the second housing includes a second open end. The second housing may be coupled to the first open end of the first housing via the second open end to connect to form a complete cabin. The cabin is internally provided with an internal accommodating chamber for accommodating at least a plurality of motors. For example, in some embodiments, the accommodating chamber is provided with a functional compartment for accommodating the controller, a pair of energy compartments arranged for accommodating the batteries, and a plurality of power compartments for satisfying power requirements and accommodating the motors.

Meanwhile, the first side plate and the second side plate are respectively arranged at two ends of the cabin in an axial direction of the first housing. The first side plate and the second side plate are configured to fix the first housing and the second housing. In some embodiments, at least one of the first side plate and the second side plate may also be integrally formed with the first housing or the second housing. The first side plate is provided with a first shaft hole arranged coaxially with an axis of the first housing and a pair of first air inlets respectively arranged on two sides of the first shaft hole in a radial direction. The second side plate includes a second air inlet arranged coaxially with the axis, and a pair of second shaft holes respectively arranged on two sides of the second air inlet in the radial direction. The first shaft hole and the second shaft hole are respectively adapted for output shafts of the motors to extend out.

In this way, the cabin may be simple in structure, high in strength and low in weight, a compact structure, an efficient assembly and an effective space utilization can be formed, and a good heat dissipation effect is maintained.

In some embodiments, the functional compartment may be arranged in the axial direction, and aligned with the second air inlet, while it may be communicated with the outside via the functional opening of the second housing. The pair of energy compartments are respectively arranged on two sides of the functional compartment in the radial direction and are aligned with the pair of first air inlets. The plurality of power compartments are arranged to be aligned with the first shaft hole and the pair of second shaft holes, so that the output shafts of the motors may extend from corresponding shaft holes. In this way, compactness of the structure can be further improved, and the space utilization rate can be further improved.

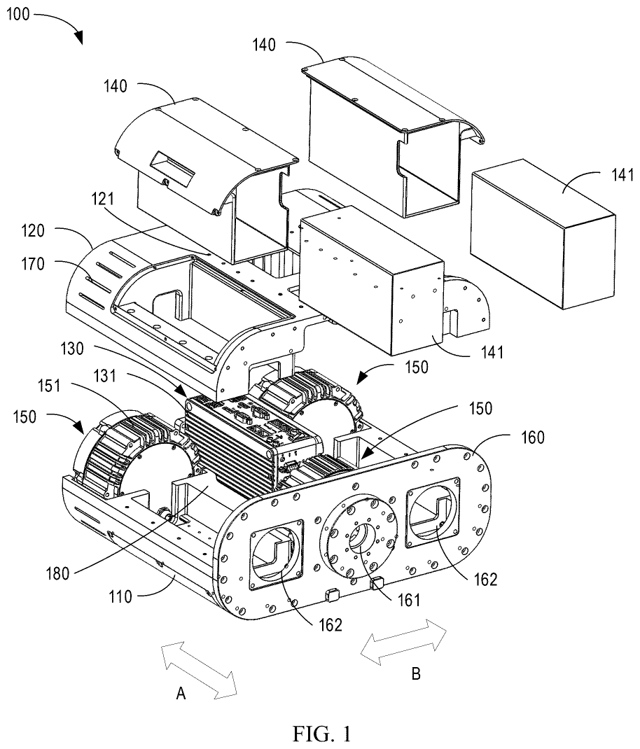

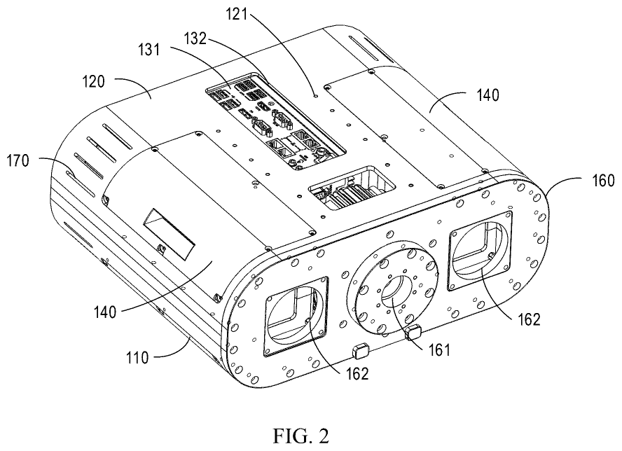

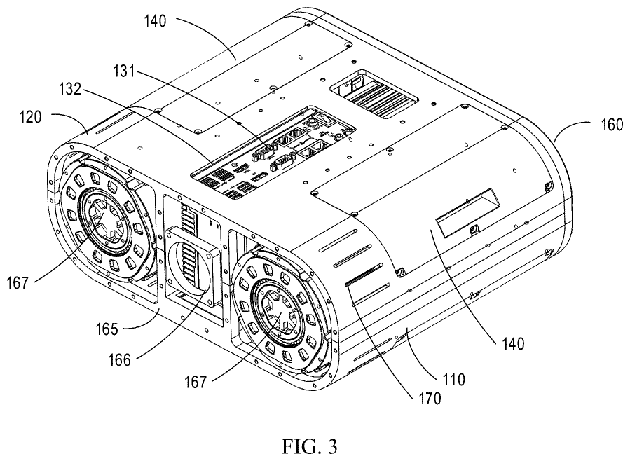

An example structure of the cabin 100 will be described below with reference to FIGS. 1-3. The robot in embodiments of the present disclosure includes a body assembly and a wheel leg assembly. The wheel leg assembly is coupled to the body assembly, and by precise control of the wheel leg assembly, the wheel leg assembly may accurately steer and swing, so that the robot may stably and efficiently move in various terrains and environments.

For ease of description of the body assembly, the cabin 100 of the body assembly in embodiments of the present disclosure will be further described below.

As shown in FIGS. 1 to 3, the cabin 100 according to the embodiment of the present disclosure generally includes a first housing 110, a second housing 120, a first side plate 160, and a second side plate 165. The first housing 110 and the second housing 120 are coupled and fixed. Meanwhile, the first side plate 160 and the second side plate 165 are arranged at two ends of the cabin 100 in the axial direction A of the first housing 110 to further fix the first housing 110 and the second housing 120. For example, the first housing 110 and the second housing 120 may be coupled by bolts.

Specifically, the first housing 110 and the second housing 120 serve as a housing of the robot cabin 100 to protect internal components (such as a controller, batteries 141, motors 151, a circuit board, etc.). The first housing 110 is made of a durable and protective material, such as metal, thermoplastic (e.g., ABS material) or plastic, to resist external physical impact and protect the internal components from damage.

Further, the first housing 110 includes a first open end. The first open end may include one or more openings, which is not specifically limited in embodiments of the present disclosure. In some embodiments, the first open end may be arranged with a seal to prevent dust or moisture and the like from entering substance that may adversely affect the internal components. Understandably, when protective measures are added, it may be ensured that they do not interfere with basic functions of the first housing 110 protecting the internal components and maintaining the structure intact.

Similar to the first housing 110, the second housing 120 also includes a second open end. It is coupled with the first open end of the first housing 110 via a second open end to enable the two housings to fit snugly together and form a closed accommodating chamber. Understandably, the two housings may be assembled and disassembled. The second housing 120 may also be made of the durable and protective material, such as metal, thermoplastic (e.g., ABS material) or plastic, to resist external physical impact and protect the internal components from damage. For example, the first housing 110 and the second housing 120 may be formed by an integrally formed machining method.

Further, the accommodating chamber provides sufficient space for internal components. The accommodating chamber includes a functional compartment 130 for accommodating a controller, a pair of energy compartments 140 for accommodating the batteries 141, and a plurality of power compartments 150 for accommodating the motor 151, and the like.

Further, the controller is located in the functional compartment 130 and is responsible for controlling all motions and operations of the robot. The batteries 141 accommodated in the energy compartment 140 provides power to the robot for continuous operation. The power bin 150 includes a motor 151 for driving the robot to move.

Specifically, the first side plate 160 and the second side plate 165 may ensure a stability of the cabin 100. They are arranged at both ends of the first housing 110 and the second housing 120 and are arranged in the axis direction A of the first housing 110, so that the first housing 110 and the second housing 120 can be fixed in correct positions, ensuring that the two are tightly connected, and making the whole cabin 100 more stable. For example, the first side plate 160 and the second side plate 165 may be coupled to the first housing 110 and the second housing 120 by fasteners such as bolts.

Further, the first side plate 160 includes a first shaft hole 161 and a pair of first air inlets 162. The first shaft hole 161 is arranged coaxially with the axis and allows the output shaft of the motor to pass through to connect the components or transmit power. At the same time, a pair of first air inlets 162 are arranged on two sides of the first shaft hole 161 in a radial direction B and are used for cooling the internal components, and hot air is discharged and cold air is fed to maintain the stable temperature inside the cabin 100.

Similarly, the second side plate 165 includes a second air inlet 166 and a pair of second shaft holes 167. The second air inlet 166 is arranged coaxially with the axis and is responsible for further air circulation to help inside cooling of the cabin 100. Meanwhile, the second shaft hole 167 is arranged on two sides of the second air inlet 166 in the radial direction B to allow the axis to pass through.

Further, the functional compartment 130 is arranged to be aligned with the second air inlet 166 in the axial direction A, so that air can flow through the functional compartment 130 and achieve cooling, and communicate with outside via a functional opening of the second housing 120. The pair of energy compartments 140 are respectively arranged on two sides of the functional compartment 130 in the radial direction B and are aligned with the pair of first air inlets 162, so that air may flow through the energy compartment 140 and achieve cooling. The plurality of power compartments 150 are respectively arranged to be aligned with the first shaft hole 161 and the pair of second shaft holes 167, so that the output shafts of the motors 151 extend from the corresponding shaft holes.

Therefore, the cabin 100 can achieve a purpose of simple structure, light weight and high strength. Meanwhile, the cabin 100 can be efficiently cooled through the first air inlet 162 and the second air inlet 166.

For the traditional cabin 100, since the motor 151 in the plurality of power compartments 150 and the controller in the functional compartment 130 may generate a large amount of heat when running, and cannot effectively discharge to the outside, the motor 151 and the controller are overheated, and performance and even damage are affected.

In order to effectively dissipate heat, the cabin 100 according to embodiments of the present disclosure is provided with a plurality of air outlets 170 at positions proximate to the power compartments 150. The air outlet 170 allows hot air to be quickly discharged and dissipated before the heat builds up to affect the performance of the motors 151. Meanwhile, the air outlet 170 may cooperate with the first air inlet 162 and the second air inlet 166 mentioned above to form an effective air flow circulation, so that the inside of the cabin 100 can be kept at a relatively low temperature.

In addition, the cabin 100 according to embodiments of the present disclosure further includes a plurality of heat dissipation fans, so that the heat dissipation fans provide cooling air for the cabin 100 from different angles, thereby further enhancing an overall heat dissipation effect of the cabin 100.

Further, the heat dissipation fans are respectively coupled to the pair of first air inlets 162 and the second air inlet 166 to ensure that the heat can be dissipated to an external environment effectively and uniformly. The heat dissipation fan of the first air inlet 162 is mainly responsible for sucking external air to flow through the energy compartment 140 to dissipate heat of the batteries 141, and discharge heat generated inside the cabin 100 from a departure port. For example, the air entering the first air inlet 162 is mainly discharged from the air outlet 170 proximate to the second shaft hole 167.

Meanwhile, the heat dissipation fan of the second air inlet 166 is responsible for sucking external air to flow through the functional compartment 130 to dissipate heat of the controller, and discharge heat generated inside the cabin 100 from the departure port. For example, the air entering the second air inlet 166 is mainly discharged from the air outlet 170 proximate to the accessory of the first shaft hole 161. In this way, it is ensured that the temperature inside the machine is stable, and a working efficiency of the robot is maintained. Of course, it should be noted that the power bin 150 may have a channel between the energy compartment 140 and the functional compartment 130 for cable routing and airflow circulation, which is not specifically limited in embodiments of the present disclosure.

Therefore, through these heat dissipation fans, the temperature of the controller, the motors 151 and the batteries 141 can be effectively controlled, so as to avoid a problem of overheating inside the cabin, and ensure a stability and a running efficiency of the robot. Meanwhile, a service life and the overall performance of the robot are also improved, and a maintenance cost is reduced. In some embodiments, a pair of energy compartments 140 are detachably arranged in the accommodating chamber to allow an operator to easily replace and maintain a batteries 141 or other energy device therein, thereby increasing robotic convenience and flexibility.

Further, the pair of energy compartments 140 may protect the batteries 141 or other energy devices from damage from the external environment by being arranged in the accommodating chamber.

By adopting this detachable manner, the energy compartment 140 can be easily inserted or removed, so that the robot becomes more convenient to replace the batteries 141 or perform other maintenance operations. This not only reduces difficulty of maintenance and maintenance but also increases the service life of the robot.

As shown in FIG. 1, in some embodiments, a reinforcing isolation structure 180 is arranged in the first housing 110 and the second housing 120, and is arranged between the functional compartment 130 and the energy compartment 140, which greatly increases a structural stability and durability of the cabin 100, and also effectively isolates the functional compartment 130 from the energy compartment 140.

Further, the reinforcing isolation structure 180 is a part for enhancing strength and stability of the cabin 100. Arranging the reinforcement isolation structure 180 between the functional compartment 130 and the energy compartment 140 may provide additional support such that the cabin 100 can still maintain a good operational state when faced with vibration or impact.

In addition, presence of the reinforcement isolation structure 180 also helps to prevent potential deformation issues of the cabin 100. This is particularly important for the space connecting the batteries 141 (energy compartment 140) and the controller (functional compartment 130) operating the robot. Both parts require structural integrity to ensure normal operation of the robot.

In some embodiments, when the cabin 100 is supported by the wheel leg structure, the second housing 120 is substantially in a vertically upward state, which not only acts as a protective housing but also serves as a platform to carry additional external devices. Meanwhile, expansibility is provided for the robot.

It will be appreciated that external devices coupled on the platform, such as sensors, wireless communication devices, additional power modules, and even other modules that provide specific functionality. This is not specifically limited in embodiments of the present disclosure.

Further, by arranging a plurality of coupling portions 121 on the outer side wall of the second housing 120, the plurality of coupling portions 121 are used for connecting external devices to meet requirements that the external devices can be disassembled and replaced at any time, so that convenience is brought to an operator, and adaptability and flexibility of the robot can also be greatly improved.

As shown in FIG. 1, in some embodiments, the first opening end, the second opening end, a first side wall of the first side plate coupled with the first housing 110 and the second housing 120 and a second side wall of the second side plate 165 coupled with the first housing 110 and the second housing 120 are subjected to thickening treatment, so as to provide stronger mechanical strength, prevent collision and other forms of physical damage. This processing manner can improve the durability of the cabin 100 and enhance its resistance to various environmental conditions.

In addition, the thickening process may make the connection between the first housing 110 and the second housing 120 more secure. Meanwhile, the first side plate 160 and the second side plate 165 and the first housing 110 and the second housing 120 can also ensure firm connection.

In some embodiments, the cabin 100 further includes a functional opening 132 arranged on an outer wall of the second housing 120 away from the first housing 110. Further, the functional opening 132 is formed on an outer wall for exposing an interface unit 131 of the controller, thereby facilitating the connection of the robot with the external devices. In some embodiments, the cabin further includes a cover for detachably closing the functional opening 132.

Based on the pods 100 described above, the body assembly will be further described below. A body assembly according to embodiments of the present disclosure generally includes a controller, a plurality of motors 151, and a pair of batteries 141. Specifically, as described above, the controller is responsible for accommodating and processing instructions operator or data from sensors and then converting those information into signals that the motor 151 may understand. Such a signal may control the rotation of the motor 151 so that the action of the robot may be determined.

Further, a controller is coupled in a functional compartment 130 of the cabin 100 and includes an interface unit 131. The interface unit 131 may be connected to other components through various interfaces via a functional opening 132 of a second housing 120. A plurality of motors 151 are respectively arranged in the power compartment 150 of the cabin 100 and adapted to be electrically connected with the controller. Each motor 151 corresponds to one or more particular mechanical actions, such as steer, travel, or lift of a robotic arm.

Meanwhile, a pair of batteries 141 are detachably arranged in the energy compartment 140 of the cabin 100. The batteries 141 provides the robot with necessary power, whether it is for work of the controller or power of the drive motor 151. During running of the robot, the energy compartment 140 enables the batteries 141 to provide stable power to the motor 151 in the power compartment 150 through the controller.

In some embodiments, the body assembly further includes a circuit board, which is a bridge connecting the batteries 141, the controller, and the motor 151, while also responsible for power management and signal transmission of the entire robot. For example, a PCB circuit board. The pair of batteries 141 power the PCB circuit board in parallel. The PCB circuit board may withstand a current of up to 200 A, and the PCB circuit board may be arranged with a location measurement unit (LMU) for detecting various motion parameters (e.g., parameters such as acceleration, speed, and the like) and positioning, and arranging multiple CAN buses and 485 buses for external devices (e.g., the joint motors 151) to communicate.

It can be seen from the above description that the cabin 100 according to embodiments of the present disclosure can be combined more compactly to achieve various effects of simple structure, high cabin strength, small weight, high assembly efficiency, and the like, and meanwhile, utilization rate of space can be effectively improved. In addition, by reasonably setting positions of the air outlet and the air inlet, a good heat dissipation effect inside the cabin is ensured.

Various implementations of the present disclosure have been described above, which are exemplary, not exhaustive, and are not limited to the implementations disclosed. Many modifications and variations will be apparent to those of ordinary skill in the art without departing from the scope and spirit of the various implementations illustrated. The selection of the terms used herein is intended to best explain the principles of the implementations, practical applications, or improvements to techniques in the marketplace, or to enable others of ordinary skill in the art to understand the various implementations disclosed herein.

I/We claim:

1. A cabin for a mobile robot, comprising:
a first housing comprising a first open end;
a second housing comprising a second open end and adapted to be coupled on the first open end of the first housing via the second open end to form an accommodating chamber that accommodates at least a plurality of motors; and
a first side plate and a second side plate respectively arranged at two ends of the first housing and the second housing in an axial direction of the first housing to fix the first housing and the second housing, the first side plate comprising a first shaft hole arranged coaxially with an axis of the first housing and a pair of first air inlets respectively arranged on two sides of the first shaft hole in a radial direction, and the second side plate comprising a second air inlet arranged coaxially with the axis, and a pair of second shaft holes respectively arranged on two sides of the second air inlet in the radial direction,
wherein output shafts of the plurality of motors are adapted to extend from the first shaft hole and the pair of second shaft holes, respectively.

2. The cabin of claim 1, wherein the accommodating chamber is adapted to receive a functional compartment for accommodating a controller, a pair of energy compartments for accommodating batteries, respectively, and a plurality of power compartments for accommodating the plurality of motors, respectively.

3. The cabin of claim 2, wherein the functional compartment is arranged to be aligned with the second air inlet in the axial direction and is communicated with outside via a functional opening of the second housing, the pair of energy compartments are respectively arranged on two sides of the functional compartment in the radial direction and are aligned with the pair of first air inlets, and the plurality of power compartments are respectively arranged to be aligned with the first shaft hole and the pair of second shaft holes, so that the output shafts of the motors extend from corresponding shaft holes.

4. The cabin of claim 2, wherein the first housing and the second housing have a plurality of air outlets at positions proximate to the plurality of power compartments.

5. The cabin of claim 2, wherein the pair of energy compartments are detachably arranged in the accommodating chamber.

6. The cabin of claim 2, wherein the first housing and the second housing comprise:
a reinforcing isolation structure arranged between the functional compartment and the energy compartment.

7. The cabin of claim 2, wherein an exterior of the second housing away from a side of the first housing is configured as a platform and comprises a plurality of coupling portions for coupling an external device to the cabin.

8. The cabin of claim 1, wherein the first open end, the second open end, a first side wall of the first side plate coupled with the first housing and the second housing and a second side wall of the second side plate coupled with the first housing and the second housing are subjected to thickening treatment.

9. The cabin of claim 1, further comprising:
a functional opening arranged on an outer wall of the second housing away from the first housing to expose an interface unit for a controller to connect an external component.

10. A body assembly, comprising:
the cabin for a mobile robot, the cabin comprising:
a first housing comprising a first open end;
a second housing comprising a second open end and adapted to be coupled on the first open end of the first housing via the second open end to form an accommodating chamber that accommodates at least a plurality of motors; and
a first side plate and a second side plate respectively arranged at two ends of the first housing and the second housing in an axial direction of the first housing to fix the first housing and the second housing, and the first side plate comprising a first shaft hole arranged coaxially with an axis of the first housing and a pair of first air inlets respectively arranged on two sides of the first shaft hole in a radial direction, the second side plate comprising a second air inlet arranged coaxially with the axis, and a pair of second shaft holes respectively arranged on two sides of the second air inlet in the radial direction,
wherein output shafts of the plurality of motors are adapted to extend from the first shaft hole and the pair of second shaft holes, respectively;
a controller coupled in a functional compartment of the cabin and comprising an interface unit adapted to be coupled to an external component via a functional opening of a second housing;
a plurality of motors respectively coupled in a power compartment of the cabin and adapted to be electrically connected to the controller; and
a pair of batteries detachably arranged in an energy compartment of the cabin and adapted to provide power to the motors via the controller.

11. The body assembly of claim 10, wherein the accommodating chamber is adapted to receive a functional compartment for accommodating a controller, a pair of energy compartments for accommodating batteries, respectively, and a plurality of power compartments for accommodating the plurality of motors, respectively.

12. The body assembly of claim 11, wherein the functional compartment is arranged to be aligned with the second air inlet in the axial direction and is communicated with outside via a functional opening of the second housing, the pair of energy compartments are respectively arranged on two sides of the functional compartment in the radial direction and are aligned with the pair of first air inlets, and the plurality of power compartments are respectively arranged to be aligned with the first shaft hole and the pair of second shaft holes, so that the output shafts of the motors extend from corresponding shaft holes.

13. The body assembly of claim 11, wherein the first housing and the second housing have a plurality of air outlets at positions proximate to the plurality of power compartments.

14. The body assembly of claim 11, wherein the pair of energy compartments are detachably arranged in the accommodating chamber.

15. The body assembly of claim 11, wherein the first housing and the second housing comprise:
a reinforcing isolation structure arranged between the functional compartment and the energy compartment.

16. The body assembly of claim 11, wherein an exterior of the second housing away from a side of the first housing is configured as a platform and comprises a plurality of coupling portions for coupling an external device to the cabin.

17. The body assembly of claim 10, wherein the first open end, the second open end, a first side wall of the first side plate coupled with the first housing and the second housing and a second side wall of the second side plate coupled with the first housing and the second housing are subjected to thickening treatment.

18. The body assembly of claim 10, further comprising:
a functional opening arranged on an outer wall of the second housing away from the first housing to expose an interface unit for a controller to connect an external component.

19. The body assembly of claim 10, further comprising:
a plurality of heat dissipation fans respectively coupled to a pair of first air inlets and a second air inlets of the cabin, and adapted for cooling the controller, the motors and the batteries.

20. A mobile robot, comprising the body assembly of claim 10.
